(19) United States
(12) Patent Application Publication
(10) Pub. No.: US 2025/0175161 A1
(43) Pub. Date: May 29, 2025

(54) RESIN-SEALED COMPONENT AND HIGH FREQUENCY MODULE

(71) Applicant: Murata Manufacturing Co., Ltd., Kyoto (JP)

(72) Inventor: Koji FURUTANI, Kyoto (JP)

(21) Appl. No.: 19/037,145

(22) Filed: Jan. 25, 2025

Related U.S. Application Data
(63) Continuation of application No. PCT/JP2023/025385, filed on Jul. 10, 2023.

(30) Foreign Application Priority Data
Aug. 3, 2022 (JP) 2022-124232

(51) Int. Cl. H03H 11/04

(52) U.S. Cl. CPC H03H 11/04

(57) ABSTRACT

There is provided a resin-sealed component the height of which can be easily reduced. A resin-sealed component includes a resin layer, at least one chip-type electronic component, a first inorganic thin film insulating layer, and a first thin film conductive layer. The resin layer includes a first principal surface and a second principal surface located opposite from each other. The at least one chip-type electronic component is provided inside the resin layer. The first inorganic thin film insulating layer is provided on or to the first principal surface of the resin layer. The first thin film conductive layer is provided in the first inorganic thin film insulating layer.

### CROSS REFERENCE TO RELATED APPLICATION

This is a continuation of International Application No. PCT/JP2023/025385 filed on Jul. 10, 2023 which claims priority from Japanese Patent Application No. 2022-124232 filed on Aug. 3, 2022. The contents of these applications are incorporated herein by reference in their entireties.

### BACKGROUND OF THE DISCLOSURE

### Field of the Disclosure

The present disclosure relates to a resin-sealed component and a high frequency module.

### Description of the Related Art

A semiconductor device built-in substrate module (a resin-sealed component) described in Japanese Unexamined Patent Application Publication No. 2013-105992 includes a core substrate (a resin layer), a semiconductor device (an electronic component) provided inside the core substrate, multiple insulating layers laminated on each of principal surfaces of the core substrate, and wiring layers provided on the insulating layers.

### BRIEF SUMMARY OF THE DISCLOSURE

In the semiconductor device built-in substrate module described in Japanese Unexamined Patent Application Publication No. 2013-105992, the insulating layers are formed from a resin and are therefore thick. For this reason, it is difficult to reduce the height of the semiconductor device built-in substrate module.

In view of the above-mentioned problem, a possible benefit of the present disclosure is to provide a resin-sealed component and a high frequency module, the height of which can be easily reduced.

A resin-sealed component according to an aspect of the present disclosure includes a resin layer, at least one chip-type electronic component, a first inorganic thin film insulating layer, and a first thin film conductive layer. The resin layer includes a first principal surface and a second principal surface located opposite from each other. The at least one chip-type electronic component is provided inside the resin layer. The first inorganic thin film insulating layer is provided on or to the first principal surface of the resin layer. The first thin film conductive layer is provided in the first inorganic thin film insulating layer.

A high frequency module according to an aspect of the present disclosure includes the resin-sealed component, and a mounting substrate on which the resin-sealed component is disposed.

The resin-sealed component and the high frequency module according to the above-described aspects of the present disclosure have an advantage of being easily reduced in height.

### BRIEF DESCRIPTION OF THE SEVERAL VIEWS OF THE DRAWINGS

FIG. 1 is a sectional view of a resin-sealed component according to Embodiment 1.

FIG. 2 is a circuit diagram of the resin-sealed component.

FIG. 3 is a sectional view to explain a correspondence relation between the resin-sealed component and a circuit in FIG. 2.

FIG. 4 is a circuit diagram of a resin-sealed component according to Embodiment 2.

FIG. 5 is a sectional view of the resin-sealed component.

FIG. 6 is a configuration diagram of a specific example of a resin-sealed component according to Embodiment 3.

FIG. 7 is a sectional view of the resin-sealed component.

FIG. 8 is a configuration diagram of a high frequency module that includes a resin-sealed component according to Embodiment 4.

FIG. 9 is a sectional view of the resin-sealed component.

FIG. 10 is a sectional view of a resin-sealed component according to Embodiment 5.

FIG. 11 is a sectional view of a high frequency module according to Embodiment 6.

### DETAILED DESCRIPTION OF THE DISCLOSURE

Resin-sealed components and high frequency modules according to the embodiments will be described below with reference to the drawings. Regarding the constituents described in the specification and the drawings, sizes and thicknesses described in the specification and the drawings and dimensional relations thereof are merely exemplary and these constituents are not limited to such examples described in the specification and the drawings.

### Embodiment 1

### (1) Outline

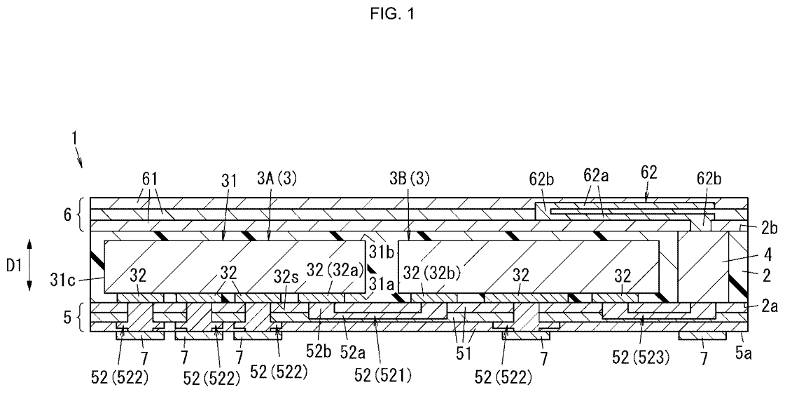

As shown in FIG. 1, a resin-sealed component 1 according to Embodiment 1 includes a resin layer 2, at least one (two in the illustrated example) chip-type electronic component 3, first inorganic thin film insulating layers 51, and a first thin film conductive layer 52. The resin layer 2 includes a first principal surface 2a and a second principal surface 2b which are located opposite from each other. The at least one chip-type electronic component 3 is provided inside the resin layer 2. The first inorganic thin film insulating layers 51 are provided on or to the first principal surface 2a of the resin layer 2 and are formed from an inorganic material. The first thin film conductive layer 52 is provided in the first inorganic thin film insulating layers 51. Here, multiple (for example, three) first inorganic thin film insulating layers 51 are laminated in the example in FIG. 1. However, a single first inorganic thin film insulating layer 51 may be provided.

According to this configuration, the first inorganic thin film insulating layers 51 are formed from the inorganic material. For this reason, it is possible to make the first inorganic thin film insulating layers 51 thinner as compared to a configuration in which a resin or a ceramic is provided on the first principal surface 2a of the resin layer 2. As a consequence, it is easier to reduce the height of the resin-sealed component 1.

The resin-sealed component 1 according to Embodiment 1 further includes second inorganic thin film insulating layers 61 and a second thin film conductive layer 62. The second inorganic thin film insulating layers 61 are provided on or to the second principal surface 2b of the resin layer 2 and are formed from an inorganic material. The second thin film conductive layer 62 is provided in the second inorganic thin film insulating layers 61. Here, multiple (for example, three) second inorganic thin film insulating layers 61 are laminated in the example in FIG. 1. However, a single second inorganic thin film insulating layer 61 may be provided.

According to this configuration, the second inorganic thin film insulating layers 61 are formed from the inorganic material. For this reason, it is possible to make the second inorganic thin film insulating layers 61 thinner as compared to a configuration in which a resin or a ceramic is provided on the second principal surface 2b of the resin layer 2. As a consequence, it is even easier to reduce the height of the resin-sealed component 1 in the configuration in which the inorganic thin film insulating layers (the first inorganic thin film insulating layers 51 and the second inorganic thin film insulating layers 61) and the thin film conductive layers (the first thin film conductive layer 52 and the second thin film conductive layer 62) are provided on or to the respective principal surfaces (the first principal surface 2a and the second principal surface 2b) of the resin layer 2. Here, the second inorganic thin film insulating layers 61 and the second thin film conductive layer 62 may be absent.

### (2) Detailed Configurations

As shown in FIG. 1, the resin-sealed component 1 according to Embodiment 1 is a component obtained by forming wiring layers (a first wiring layer 5 and a second wiring layer 6) each having a thin film structure on the respective principal surfaces (the first principal surface 2a and the second principal surface 2b) of the resin layer 2 having the at least one chip-type electronic component 3 built-in, and providing the wiring layers 5 and 6 with circuits to be connected to the chip-type electronic component 3. The resin-sealed component 1 includes the resin layer 2, the at least one chip-type electronic component 3, multiple connection electrodes 4, the first wiring layer 5, the second wiring layer 6, and multiple external terminal electrodes 7.

For example, the chip-type electronic component 3 is a surface mount device, or more specifically, any of an IC (integrated circuit) chip, a transmission filter, a reception filter, a power amplifier, a low noise amplifier, and the like. Although a case of providing two chip-type electronic components 3 is illustrated in the example in FIG. 1, at least one chip-type electronic component 3 needs to be provided therein. In the case of distinguishing the two chip-type electronic components 3, the two chip-type electronic components 3 will be denoted by chip-type electronic components 3A and 3B. The chip-type electronic components 3 are provided inside the resin layer 2, thereby being sealed in the resin layer 2.

Each chip-type electronic component 3 includes a component body 31 and multiple pad electrodes 32. The component body 31 is a portion of the chip-type electronic component 3 other than the pad electrodes 32, and includes a circuit for implementing various functions of the chip-type electronic component 3 (this circuit may be hereinafter referred to as a functional circuit in some cases). The component body 31 has a substantially rectangular parallelepiped shape, for example. The component body 31 has two principal surfaces (a third principal surface 31a and a fourth principal surface 31b) which are located opposite from each other, and an outer peripheral surface 31c that joins an outer peripheral side of the third principal surface 31a to an outer peripheral side of the fourth principal surface 31b. The multiple pad electrodes 32 are portions to be electrically connected to an external circuit (which is the first wiring layer 5 in Embodiment 1). The multiple pad electrodes 32 are disposed on the third principal surface 31a of the component body 31. The multiple pad electrodes 32 are electrically connected to the above-mentioned functional circuit.

Multiple (two in the illustrated example) chip-type electronic components 3 are provided in Embodiment 1. The multiple chip-type electronic components 3 are disposed so as to be arranged on a virtual plane. The respective pad electrodes 32 of the multiple chip-type electronic components 3 are directed to the same side (the first principal surface 2a side to be described later of the resin layer 2 in the example in FIG. 1) as one another.

The resin layer 2 is a member for providing the chip-type electronic components 3 inside. The resin layer 2 has a flat plate shape in a quadrangular form in plan view. The resin layer 2 is formed from a heat resisting material, for example. The material of the resin layer 2 is epoxy resin, for instance. However, the material is not limited to epoxy resin. An inorganic filler may be mixed with the resin layer 2. The resin layer 2 includes the two principal surfaces (the first principal surface 2a and the second principal surface 2b) which are located opposite from each other.

The chip-type electronic components 3 are provided inside the resin layer 2. Among outer surfaces of the chip-type electronic components 3, the resin layer 2 exposes contact surfaces 32s of the pad electrodes 32 from the first principal surface 2a, and covers portions (the third principal surfaces 31a, the fourth principal surfaces 31b, the outer peripheral surfaces 31c, and the like) other than the contact surfaces 32s of the pad electrodes 32. The contact surfaces 32s are flush with the first principal surface 2a.

The multiple connection electrodes 4 are conductive members for electrically connecting the first wiring layer 5 to the second wiring layer 6. Each connection electrode 4 has a columnar shape, for example, and is provided in the resin layer 2 so as to penetrate the resin layer 2 in a thickness direction D1 thereof. End surfaces on respective sides of each connection electrode 4 in a thickness direction D1 thereof are exposed from the first principal surface 2a and the second principal surface 2b of the resin layer 2. In the example in FIG. 1, the connection electrodes 4 are disposed on a side of the chip-type electronic component 3B opposite from the chip-type electronic component 3A. Nonetheless, the connection electrodes 4 can be disposed at any position in the resin layer 2. For example, the connection electrodes 4 may be disposed between the chip-type electronic components 3A and 3B.

The first wiring layer 5 is a wiring layer provided with wiring and a circuit to be connected to the chip-type electronic component 3. The first wiring layer 5 is provided on the first principal surface 2a of the resin layer 2. The first wiring layer 5 includes the first inorganic thin film insulating layers 51 and the first thin film conductive layer 52.

The multiple (for example, three) first inorganic thin film insulating layers 51 are provided on or to the first principal surface 2a of the resin layer 2. Here, the first inorganic thin film insulating layers 51 are not limited to have multiple layers and a single layer may be provided. Each first inorganic thin film insulating layer 51 is formed from the inorganic material. Examples of the inorganic material include an oxide film (such as silicon oxide (SiO₂) and alumina (Al₂O₃)), a nitride film (such as silicon nitride (SiNₓ)), an oxynitride film (such as an aluminum oxynitride film (AlON) and a silicon oxynitride film (SiON)), and silicon carbide (SiC).

The first thin film conductive layer 52 is provided in the first inorganic thin film insulating layers 51. To be more precise, the first thin film conductive layer 52 is provided between the multiple first inorganic thin film insulating layers 51. Here, the first thin film conductive layer 52 may be provided on an outer surface of the first inorganic thin film insulating layer 51 being the outermost layer of the multiple first inorganic thin film insulating layers 51. The first thin film conductive layer 52 forms the wiring and the circuit connected to each chip-type electronic component 3 provided inside the resin layer 2. For example, the above-mentioned circuit is formed by using a passive element (such as a capacitor, an inductor, and a resistor). Although the above-mentioned circuit is assumed to be formed by using only the passive element, the circuit may include an active element. The above-mentioned circuit is not an essential configuration but is formed as needed. The first thin film conductive layer 52 is made of a metal such as copper (Cu), silver (Ag), and gold (Au).

The first thin film conductive layer 52 includes multiple conductive layers 52a and multiple via electrodes 52b. Note that a single conductive layer 52a and a single via electrode 52b may be provided. The multiple conductive layers 52a are provided between the multiple first inorganic thin film insulating layers 51. The multiple via electrodes 52b are provided so as to penetrate at least one conductive layer 52a in a thickness direction thereof, and electrically connect two conductive layers 52a out of the multiple conductive layers 52a. The via electrodes 52b electrically connect the conductive layers 52a to other conductors (the pad electrodes 32 of the chip-type electronic components 3, the external terminal electrodes 7, or the connection electrodes 4). For example, the first thin film conductive layer 52 includes a connection electrode layer 521 that electrically connects pad electrodes 32a and 32b of the two chip-type electronic components 3A and 3B to each other, connection electrode layers 522 that electrically connect the chip-type electronic components 3A and 3B to the external terminal electrodes 7, and connection electrode layers 523 that electrically connect the chip-type electronic components 3A and 3B to the connection electrodes 4. The connection electrode layers 521 to 523 are formed as needed.

The second wiring layer 6 is a wiring layer that forms the circuit connected to the chip-type electronic component 3 through the connection electrodes 4 and the first wiring layer 5. The second wiring layer 6 is provided on the second principal surface 2b of the resin layer 2. The second wiring layer 6 includes the second inorganic thin film insulating layers 61 and the second thin film conductive layer 62.

The multiple (for example, three) second inorganic thin film insulating layers 61 are provided on or to the second principal surface 2b of the resin layer 2. Here, the second inorganic thin film insulating layers 61 are not limited to have multiple layers and a single layer may be provided. Each second inorganic thin film insulating layer 61 is formed from the inorganic material. Examples of the inorganic material include an oxide film (such as silicon oxide (SiO₂) and alumina (Al₂O₃)), a nitride film (such as silicon nitride (SiNₓ)), an oxynitride film (such as an aluminum oxynitride film (AlON) and a silicon oxynitride film (SiON)), and silicon carbide (SiC). Here, the second inorganic thin film insulating layer 61 may be formed from the same inorganic material as that of the first inorganic thin film insulating layer 51 or a different material therefrom. At least one of the first inorganic thin film insulating layer 51 and the second inorganic thin film insulating layer 61 may be any of the oxide film, the nitride film, and the oxynitride film.

The second thin film conductive layer 62 is provided in the multiple second inorganic thin film insulating layers 61. To be more precise, the second thin film conductive layer 62 is provided between the multiple second inorganic thin film insulating layers 61. Here, the second thin film conductive layer 62 may be provided on an outer surface of the second inorganic thin film insulating layer 61 being the outermost layer of the multiple second inorganic thin film insulating layers 61. The second thin film conductive layer 62 forms the circuit electrically connected to each chip-type electronic component 3 through the first wiring layer 5 and the connection electrodes 4. For example, the above-mentioned circuit is formed by using a passive element (such as a capacitor, an inductor, and a resistor). Although the above-mentioned circuit is assumed to be formed by using only the passive element, the circuit may include an active element. The second thin film conductive layer 62 is made of a metal such as copper (Cu), silver (Ag), and gold (Au).

The second thin film conductive layer 62 includes multiple conductive layers 62a and multiple via electrodes 62b. Note that a single conductive layer 62a and a single via electrode 62b may be provided. The multiple conductive layers 62a are provided between the multiple second inorganic thin film insulating layers 61. The multiple via electrodes 62b are provided so as to penetrate at least one conductive layer 62a in a thickness direction thereof, and electrically connect two conductive layers 62a out of the multiple conductive layers 62a. The via electrodes 62b electrically connect the conductive layers 62a to the connection electrodes 4. Each second inorganic thin film insulating layer 61 overlaps at least one chip-type electronic component 3 in plan view in the thickness direction D1 of the resin layer 2. In the example in FIG. 1, the second thin film conductive layer 62 overlaps the chip-type electronic component 3B in plan view in the thickness direction D1 of the resin layer 2. Note that the expression “A overlaps B” represents a state where at least part of A overlaps at least part of B.

The multiple external terminal electrodes 7 are portions to be electrically connected to an external mounting substrate (not shown). The external terminal electrodes 7 are disposed on an outer principal surface (that is to say, the principal surface located on the side opposite from the resin layer 2) 5a of the first wiring layer 5. The multiple external terminal electrodes 7 include the external terminal electrodes 7 electrically connected to the first thin film conductive layer 52. The multiple external terminal electrodes 7 include the external terminal electrodes 7 electrically connected to the second thin film conductive layer 62 through the first thin film conductive layer 52 and the connection electrodes 4. The multiple external terminal electrodes 7 include the external terminal electrodes 7 disposed so as to overlap the chip-type electronic components 3 in plan view in the thickness direction D1 of the resin layer 2.

### (3) Manufacturing Method

An example of a manufacturing method of the resin-sealed component 1 will be described with reference to FIG. 1.

First, the chip-type electronic components 3 and the connection electrodes 4 in a state of being arranged at predetermined locations are provided inside the resin layer 2 by sealing the chip-type electronic components 3 and the connection electrodes 4 with the resin material for the resin layer 2. In this instance, the contact surface 32s of each pad electrode 32 of the chip-type electronic component 3 and one end surface of each connection electrode 4 are exposed to the first principal surface 2a of the resin layer 2. The other end surface of each connection electrode 4 is exposed to the second principal surface 2b of the resin layer 2. Here, the present disclosure is not limited to the configuration to expose the contact surface 32s of each pad electrode 32 and the one end surface as well as the other end surface of each connection electrode 4 at the time of sealing with the resin. For example, the contact surface 32s of each pad electrode 32 and the one end surface as well as the other end surface of each connection electrode 4 may be covered with the resin layer 2 at the time of sealing with the resin and may be exposed after the formation of the resin layer 2 by scraping the resin layer 2. The present disclosure is not limited to the configuration to provide the connection electrodes 4 inside the resin layer 2 together with the chip-type electronic components 3 at the time of sealing with the resin. For example, the connection electrodes 4 may be provided inside the resin layer 2 by drilling through holes in the resin layer 2 after the sealing the chip-type electronic components 3 with the resin and then filling the through holes with the material for the connection electrodes 4.

Then, the first wiring layer 5 (namely, the first inorganic thin film insulating layers 51 and the first thin film conductive layer 52) is formed on the first principal surface 2a of the resin layer 2 in accordance with a vacuum film formation method (such as a vacuum vapor deposition method and a sputtering method), for example.

To be more precise, an insulating film is formed in accordance with the vacuum film formation method on the first principal surface 2a of the resin layer 2 by using the material (the inorganic material) for the first inorganic thin film insulating layers 51. Then, a portion other than unnecessary portions (portions to be provided with through holes for the via electrodes 52b, for example) of the formed insulating film is subjected to mask processing, and the unnecessary portion is removed by etching. Thus, the first inorganic thin film insulating layer 51 of the first layer provided with the through holes is formed from the insulating film. Then, the via electrodes 52b are formed in accordance with the vacuum film formation method in the through holes of the first inorganic thin film insulating layer 51 of the first layer by using the material for the first thin film conductive layer 52. Subsequently, a pattern of the conductive layers 52a is formed in accordance with the vacuum film formation method on an outer principal surface of the first inorganic thin film insulating layer 51 of the first layer by using the material for the first thin film conductive layer 52. In this way, the first inorganic thin film insulating layers 51 and the first thin film conductive layer 52 (the conductive layers 52a and the via electrode 52b) are alternately formed. The first inorganic thin film insulating layer 51 formed last (the outermost layer) is provided with no conductive layers 52a but only with the via electrodes 52b to be connected to the external terminal electrodes 7. Thus, the first inorganic thin film insulating layers 51 are formed on the first principal surface 2a of the resin layer 2, and the first thin film conductive layer 52 is formed in the first inorganic thin film insulating layers 51. Then, the multiple external terminal electrodes 7 are formed on the outer principal surface 5a of the first wiring layer 5 in accordance with the vacuum film formation method.

Thereafter, the second wiring layer 6 (namely, the second inorganic thin film insulating layers 61 and the second thin film conductive layer 62) is formed on the second principal surface 2b of the resin layer 2 in accordance with the vacuum film formation method in the same manufacturing method as the manufacturing method of the first wiring layer 5. In this instance, none of the conductive layers 62a and the via electrodes 62b is formed in the second inorganic thin film insulating layer 61 being the outermost layer out of the multiple second inorganic thin film insulating layers 61. Although Embodiment 1 exemplifies the case where none of the conductive layers 62a and the via electrodes 62b is formed in the second inorganic thin film insulating layer 61 of the outermost layer, the conductive layers 62a and the via electrodes 62b may be formed in the second inorganic thin film insulating layer 61 of the outermost layer. The resin-sealed component 1 is manufactured as described above.

Since the first inorganic thin film insulating layers 51 are formed from the inorganic material in this manufacturing method, it is easier to form the first inorganic thin film insulating layers 51 into a thin film form by using the vacuum film formation method. Moreover, the formation of the first inorganic thin film insulating layers 51 in accordance with the vacuum film formation method makes it easier to form the first thin film conductive layer 52 in accordance with the vacuum film formation method as well. As a consequence, it is easier to form the entire first wiring layer 5 (namely, the first inorganic thin film insulating layers 51 and the first thin film conductive layer 52) into the thin film form. Likewise, it is easier to form the entire second wiring layer 6 into the thin film form as well.

The vacuum film formation method used in this manufacturing method can adopt the same method as a method used in a thin film formation process in a semiconductor manufacturing process. For this reason, the use of the same method as the method used in the thin film formation process in the semiconductor manufacturing process enables the formation of the first wiring layer 5 and the second wiring layer 6 with fine wiring and in a highly integrated fashion.

### (4) Specific Example of Resin-Sealed Component 1

### (4-1) Circuit Configuration of Resin-Sealed Component

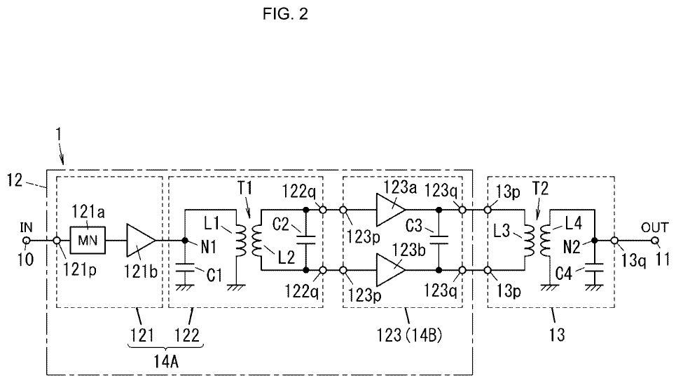

A case where the resin-sealed component 1 according to Embodiment 1 includes a power amplifier 12 and an output matching circuit 13 formed by a circuit illustrated in FIG. 2 will be given as an example. As shown in FIG. 2, the resin-sealed component 1 of this specific example includes an input terminal 10, an output terminal 11, the power amplifier 12, and the output matching circuit 13.

The input terminal 10 is a terminal to which a signal (such as a transmission signal) to be amplified by the power amplifier 12 is inputted. The output terminal 11 is a terminal that outputs an output signal from the output matching circuit 13.

The power amplifier 12 amplifies the signal inputted to the input terminal 10, and outputs the amplified signal to the output matching circuit 13. The power amplifier 12 includes a driver stage 121, an interstage matching circuit 122 (a matching circuit), and a final stage 123.

The driver stage 121 is a circuit block that amplifies the signal inputted to the input terminal 10. The driver stage 121 includes a matching circuit 121a and a first amplifier 121b. The matching circuit 121a is connected between the input terminal 10 and the first amplifier 121b, and carries out impedance matching between the circuit (not shown) connected to the input terminal 10 and the first amplifier 121b. The first amplifier 121b includes an input portion and an output portion. The input portion of the first amplifier 121b is connected to the input terminal 10 through the matching circuit 121a, and the output portion of the first amplifier 121b is connected to the interstage matching circuit 122 (to be more precise, to a node N1 to be described later). The driver stage 121 carries out impedance matching of the signal inputted to the input terminal 10 by using the matching circuit 121a, amplifies the signal subjected to the impedance matching by using the first amplifier 121b, and outputs the amplified signal to the node N1 of the interstage matching circuit 122.

The interstage matching circuit 122 is connected between the driver stage 121 and the final stage 123, and carries out impedance matching between the driver stage 121 and the final stage 123. The interstage matching circuit 122 includes capacitors C1 and C2 and a transformer T1. The transformer T1 includes a primary coil L1 and a secondary coil L2. One end (a first end) of the primary coil L1 is connected to ground and the other end (a second end) of the primary coil L1 is connected to the ground through the capacitor C1. The output portion of the first amplifier 121b is connected to the node N1 between the capacitor C1 and the primary coil L1. Both ends of the secondary coil L2 are connected to input portions of two second amplifiers 123a and 123b of the final stage 123 to be described later. Moreover, the capacitor C2 is connected between both ends of the secondary coil L2. The interstage matching circuit 122 carries out impedance matching of the output signal from the output portion of the first amplifier 121b by using the primary coil L1, the secondary coil L2, and the capacitors C1 and C2, and outputs this signal to the input portions of the two second amplifiers 123a and 123b of the final stage 123 to be described later.

The final stage 123 is a circuit block that amplifies the output signal from the interstage matching circuit 122. Specifically, in this power amplifier 12, the transmission signal is amplified by using the two stages, namely, the driver stage 121 and the final stage 123. The final stage 123 includes the two second amplifiers 123a and 123b, and a capacitor C3. Each of the second amplifiers 123a and 123b includes an input portion and an output portion. The input portion of the second amplifier 123a is connected to one end (a first end) of the secondary coil L2 of the interstage matching circuit 122, and the input portion of the second amplifier 123b is connected to the other end (a second end) of the secondary coil L2. The output portion of the second amplifier 123a is connected to one end (a first end) of a primary coil L3 of the output matching circuit 13 to be described later, and the output portion of the second amplifier 123b is connected to the other end (a second end) of the primary coil L3 of the output matching circuit 13 to be described later. That is to say, the output matching circuit 13 is connected to the output portions of the two second amplifiers 123a and 123b. The capacitor C3 is connected between the output portions of the two second amplifiers 123a and 123b. The final stage 123 individually amplifies the output signals from both ends of the secondary coil L2 of the interstage matching circuit 122 by using the two second amplifiers 123a and 123b, and outputs the signals to both ends of the primary coil L3 of the output matching circuit 13 to be described later.

The first amplifier 121b of the driver stage 121 is an amplifier on a signal input side (that is to say, the input terminal 10 side) out of the multiple amplifiers 121b, 123a, and 123b that constitute the power amplifier 12. The second amplifiers 123a and 123b of the final stage 123 are amplifiers on a signal output side (that is to say, the output terminal 11 side) out of the multiple amplifiers 121b, 123a, and 123b that constitute the power amplifier 12.

The output matching circuit 13 is connected between the power amplifier 12 and the output terminal 11, and carries out impedance matching between the power amplifier 12 and a circuit (not shown) connected to the output terminal 11. The output matching circuit 13 includes a transformer T2 and a capacitor C4. The transformer T2 includes the primary coil L3 and a secondary coil L4. Both ends of the primary coil L3 are connected to the output portions of the two second amplifiers 123a and 123b of the final stage 123. One end (a first end) of the secondary coil L4 is connected to the ground, and the other end (a second end) of the secondary coil L4 is connected to the ground through the capacitor C4. The output terminal 11 is connected to a node N2 between the capacitor C4 and the secondary coil L4. The output matching circuit 13 synthesizes the output signals from the output portions of the two second amplifiers 123a and 123b of the interstage matching circuit 122 into one signal by using the transformer T2, then carries out the impedance matching by using the primary coil L3, the secondary coil L4, and the capacitor C4, and outputs this signal from the output terminal 11.

Now, a supplementary explanation will be given regarding a configuration of the circuit in FIG. 2. An input portion 121p of the driver stage 121 is disposed between the input terminal 10 and an input portion of the matching circuit 121a. Two output portions 122q of the interstage matching circuit 122 are disposed in the vicinity on the final stage 123 side of a connecting point where one end of the secondary coil L2 is connected to one end of the capacitor C2 and in the vicinity on the final stage 123 side of a connecting point where the other end of the secondary coil L2 is connected to the other end of the capacitor C2, for example. Two input portions 123p of the final stage 123 are disposed in the vicinity of the input portions of the two second amplifiers 123a and 123b, for example. Two output portions 123q of the final stage 123 are disposed in the vicinity on the output matching circuit 13 side of a connecting point of the output portion of the second amplifier 123a to one end (a first end) of the capacitor C3 and in the vicinity on the output matching circuit 13 side of a connecting point of the output portion of the second amplifier 123b to the other end (a second end) of the capacitor C3, for example. Input portions 13p of the output matching circuit 13 are disposed in the vicinity of both ends of the primary coil L3. An output portion 13q of the output matching circuit 13 is disposed between the node N2 and the output terminal 11.

In this specific example, the driver stage 121 and the interstage matching circuit 122 are included in a single IC chip (a first IC chip 14A), for example. The final stage 123 is included in another IC chip (a second IC chip 14B).

### (4-2) Correspondence Relation Between Resin-Sealed Component 1 and Circuit

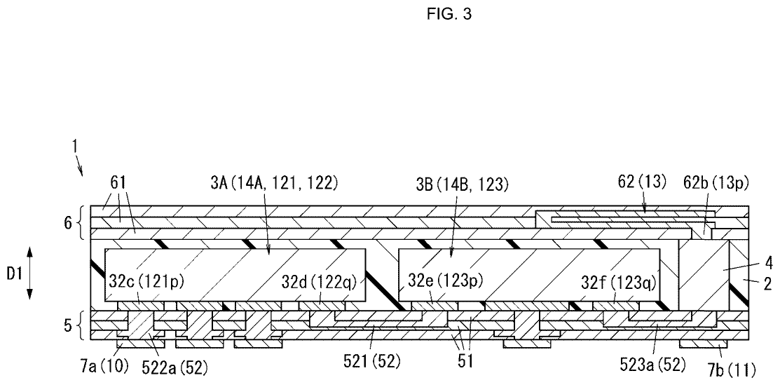

A correspondence relation between the resin-sealed component 1 and the circuit in FIG. 2 will be explained with reference to FIG. 3.

The chip-type electronic component 3A of the resin-sealed component 1 is the first IC chip 14A that includes the driver stage 121 and the interstage matching circuit 122. That is to say, the interstage matching circuit 122 is included in the first IC chip 14A together with the driver stage 121. A pad electrode 32c of the chip-type electronic component 3A is the input portion 121p of the driver stage 121. The pad electrode 32c is connected to an external terminal electrode 7a being the input terminal 10 through a connection electrode layer 522a of the first thin film conductive layer 52. A pad electrode 32d of the chip-type electronic component 3A is one of the two output portions 122q of the interstage matching circuit 122. The pad electrode 32d is connected to a pad electrode 32e of the chip-type electronic component 3B (that is to say, one of the two input portions 123p of the final stage 123) through the connection electrode layer 521 of the first thin film conductive layer 52. Note that the illustration of the other pad electrode 32 out of the two output portions 122q is omitted in the example in FIG. 3.

The chip-type electronic component 3B of the resin-sealed component 1 is the second IC chip 14B that includes the final stage 123. The pad electrode 32e of the chip-type electronic component 3B is the input portion 123p of the final stage 123. The pad electrode 32e is electrically connected to the pad electrode 32d (that is to say, the output portion 122q of the interstage matching circuit 122) of the chip-type electronic component 3A through the connection electrode layer 521 of the first thin film conductive layer 52. A pad electrode 32f of the chip-type electronic component 3B is the output portion 123q of the final stage 123. The pad electrode 32f is electrically connected to the second thin film conductive layer 62 through the connection electrode layer 523 of the first thin film conductive layer 52 as well as the connection electrode 4.

The output matching circuit 13 in FIG. 2 is formed from at least one of the first thin film conductive layer 52 and the second thin film conductive layer 62 of the resin-sealed component 1 (the second thin film conductive layer 62 in the example in FIG. 3). The via electrode 62b of the second thin film conductive layer 62 is one of the two input portions 13p of the output matching circuit 13. The via electrode 62b is electrically connected to the pad electrode 32f of the chip-type electronic component 3B (that is to say, the output portion 123q of the final stage 123) through the connection electrode 4 as well as a connection electrode layer 523a of the first thin film conductive layer 52. An external terminal electrode 7b is the output terminal 11, which is electrically connected to a predetermined location of the second thin film conductive layer 62 (that is to say, the output portion 13q of the output matching circuit 13) through a not-illustrated connection electrode layer of the first thin film conductive layer 52 as well as a not-illustrated connection electrode in the resin layer 2.

The output matching circuit 13 (namely, the second thin film conductive layer 62) overlaps the chip-type electronic component 3B (namely, the second IC chip 14B) in plan view in the thickness direction D1 of the resin layer 2. Here, the expression “A overlaps B” represents a state where at least part of A overlaps at least part of B. The input terminal 10 and the output terminal 11 are constructed from predetermined two of the multiple external terminal electrodes 7.

In this specific example, the interstage matching circuit 122 is included in the first IC chip 14A together with the driver stage 121 as mentioned above. Accordingly, it is possible to reduce interposition of a junction between the driver stage 121 and the interstage matching circuit 122, which may cause impedance mismatch. This configuration makes it easier to obtain impedance matching in the interstage matching circuit 122.

In this specific example, the output matching circuit 13 is included in at least one of the first thin film conductive layer 52 and the second thin film conductive layer 62 (the second thin film conductive layer 62, for example) as mentioned above. Accordingly, the height of the resin-sealed component 1 can be easily reduced with the configuration including the output matching circuit 13. Moreover, it is possible to downsize the second IC chip 14B since the output matching circuit 13 is not included in the second IC chip 14B. The output matching circuit 13 overlaps the second IC chip 14B as mentioned above. Accordingly, it is possible to reduce an electromagnetic interference between the output matching circuit 13 and other components (such as the driver stage 121 and the interstage matching circuit 122) in the resin-sealed component 1.

In this specific example, a substrate of the first IC chip 14A including the driver stage 121 is made of silicon (Si), for example. On the other hand, a substrate of the second IC chip 14B including the final stage 123 is made of gallium arsenide (GaAs), for example. The substrate made of gallium arsenide has high performances but is expensive. On the other hand, the substrate made of silicon is inexpensive but has lower performances than those of the substrate made of gallium arsenide. In the resin-sealed component 1 of this specific example, the substrate of the first IC chip 14A including the driver stage 121 is made of silicon while the substrate of the second IC chip 14B including the final stage 123 is made of the gallium arsenide. Accordingly, it is possible to construct the resin-sealed component 1 while achieving advantages in light of the price and the performances.

### Modification

Embodiment 1 exemplifies the case of providing both the first wiring layer 5 (namely, the first inorganic thin film insulating layers 51 as well as the first thin film conductive layer 52) and the second wiring layer 6 (namely, the second inorganic thin film insulating layers 61 as well as the second thin film conductive layer 62). However, there may be a case of providing only the first wiring layer 5 out of the first wiring layer 5 and the second wiring layer 6. In this case, the circuit included in the second thin film conductive layer 62 of the second wiring layer 6 is included in the first thin film conductive layer 52 of the first wiring layer 5 instead of the second thin film conductive layer 62.

### OTHER EMBODIMENTS

Other embodiments will be described below. The following description will mainly discuss different features from those of Embodiment 1. The same constituents as those of Embodiment 1 may be denoted by the same reference signs in Embodiment 1 and explanations thereof may be omitted as appropriate.

### Embodiment 2

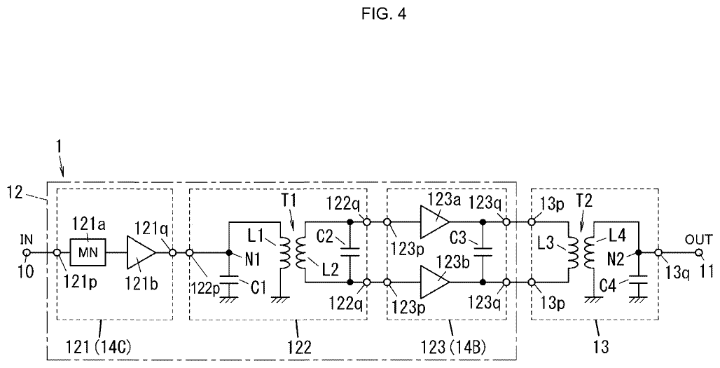

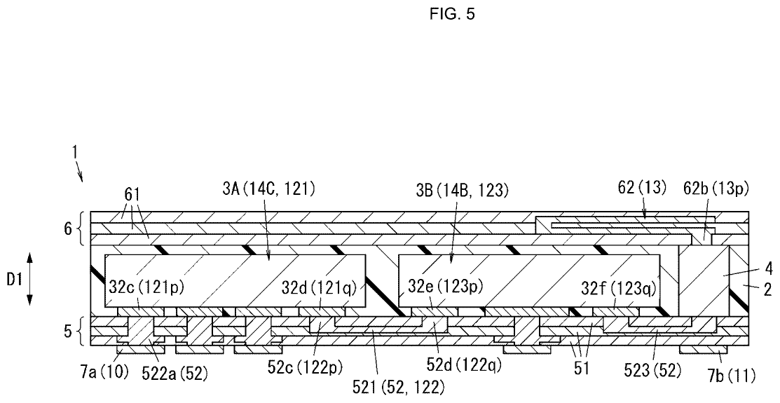

In the specific example (see FIGS. 2 and 3) of Embodiment 1, the driver stage 121 and the interstage matching circuit 122 are included together in the first IC chip 14A. On the other hand, in Embodiment 2, the driver stage 121 is included in a first IC chip 14C as shown in FIGS. 4 and 5. Then, the interstage matching circuit 122 is included in at least one of the first thin film conductive layer 52 and the second thin film conductive layer 62 (the first thin film conductive layer 52 in the example in FIGS. 4 and 5).

The resin-sealed component 1 according to Embodiment 2 includes the power amplifier 12 and the output matching circuit 13 constructed by a circuit shown in FIG. 4. The circuit in FIG. 4 is the same as the circuit in FIG. 2.

Now, a supplementary explanation will be given regarding a configuration of the circuit in FIG. 4. An output portion 121q of the driver stage 121 is disposed in the vicinity of the output portion of the first amplifier 121b. An input portion 122p of the interstage matching circuit 122 is disposed in the vicinity of the node N1. Here, as with the case in FIG. 2, reference sign 121p indicated in FIG. 4 denotes the input portion of the driver stage 121. Reference sign 122q indicated in FIG. 4 denotes the output portion of the interstage matching circuit 122. Reference sign 123p indicated in FIG. 4 denotes the input portion of the final stage 123. Reference sign 123q indicated in FIG. 4 denotes the output portion of the final stage 123. Reference sign 13p indicated in FIG. 4 denotes the input portion of the output matching circuit 13. Reference sign 13q indicated in FIG. 4 denotes the output portion of the output matching circuit 13.

A correspondence relation between the resin-sealed component 1 according to Embodiment 2 and the circuit in FIG. 4 will be explained with reference to FIG. 5. In Embodiment 2, the chip-type electronic component 3A is the first IC chip 14C that includes the driver stage 121. The pad electrode 32c of the chip-type electronic component 3A is the input portion 121p of the driver stage 121. The pad electrode 32c is connected to the external terminal electrode 7a being the input terminal 10 through the connection electrode layer 522a of the first thin film conductive layer 52. The pad electrode 32d of the chip-type electronic component 3A is the output portion 121q of the driver stage 121. The pad electrode 32d is connected to the pad electrode 32e of the chip-type electronic component 3B (that is to say, one of the two input portions 123p of the final stage 123) through the connection electrode layer 521 of the first thin film conductive layer 52.

The chip-type electronic component 3B of Embodiment 2 is the second IC chip 14B that includes the final stage 123. This second IC chip 14B is the same as the second IC chip 14B of the specific example of Embodiment 1, and detailed explanations will therefore be omitted.

The interstage matching circuit 122 of Embodiment 2 is included in the first thin film conductive layer 52, for example. To be more precise, the interstage matching circuit 122 is formed from the connection electrode layer 521 out of the first thin film conductive layer 52, which connects the pad electrode 32d of the chip-type electronic component 3A to the pad electrode 32e of the chip-type electronic component 3B. A via electrode 52c of the connection electrode layer 521 is the input portion 122p of the interstage matching circuit 122, which is connected to the pad electrode 32d of the chip-type electronic component 3A (that is to say, the output portion 121q of the driver stage 121). A via electrode 52d of the connection electrode layer 521 is the output portion 122q of the interstage matching circuit 122, which is connected to the pad electrode 32e of the chip-type electronic component 3B (that is to say, the input portion 123p of the final stage 123).

The output matching circuit 13 of Embodiment 2 is included in the second thin film conductive layer 62 as with the specific example of Embodiment 1. Accordingly, detailed explanations of the output matching circuit 13 will be omitted.

As described above, in Embodiment 2, the interstage matching circuit 122 is included in the first thin film conductive layer 52, and the first IC chip 14C therefore does not include the interstage matching circuit 122. As a consequence, it is possible to downsize the first IC chip 14C in an amount equivalent to the interstage matching circuit 122 not included therein.

### Embodiment 3

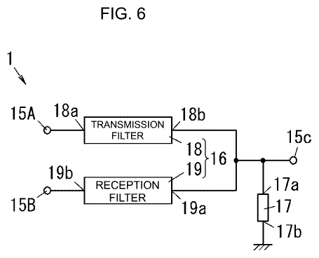

Embodiment 3 will exemplify a case where the resin-sealed component 1 includes a duplexer 16 and a matching circuit 17 shown in FIG. 6.

As shown in FIG. 6, the resin-sealed component 1 according to Embodiment 3 includes an input terminal 15A, an output terminal 15B, an input/output terminal 15C, the duplexer 16, and the matching circuit 17 connected to the duplexer 16.

Transmission signals are inputted to the input terminal 15A. The output terminal 15B outputs the output signals (reception signals) from a reception filter 19 of the duplexer 16 to be described later. The input/output terminal 15C outputs the output signals (transmission signals) from a transmission filter 18 of the duplexer 16 to be described later, and accepts the input of the reception signals to be processed by the reception filter 19 of the duplexer 16.

The duplexer 16 includes the transmission filter 18 (a transmission component) and the reception filter 19 (a reception component). The transmission filter 18 includes an input portion 18a and an output portion 18b. The input portion 18a of the transmission filter 18 is connected to the input terminal 15A. The output portion 18b of the transmission filter 18 is connected to the input/output terminal 15C. The transmission filter 18 allows passage of a transmission signal in a first frequency band out of the transmission signals that are inputted from the input terminal 15A to the input portion 18a, and outputs the relevant transmission signal from the output portion 18b to the input/output terminal 15C. The reception filter 19 includes an input portion 19a and an output portion 19b. The input portion 19a of the reception filter 19 is connected to the input/output terminal 15C. The output portion 19b of the reception filter 19 is connected to the output terminal 15B. The reception filter 19 allows passage of a reception signal in a second frequency band out of the reception signals that are inputted from the input/output terminal 15C to the input portion 19a, and outputs the relevant reception signal from the output portion 19b to the output terminal 15B.

The matching circuit 17 is connected between the input/output terminal 15C and the ground, and carries out impedance matching between a circuit (not shown) connected to the input/output terminal 15C and the duplexer 16.

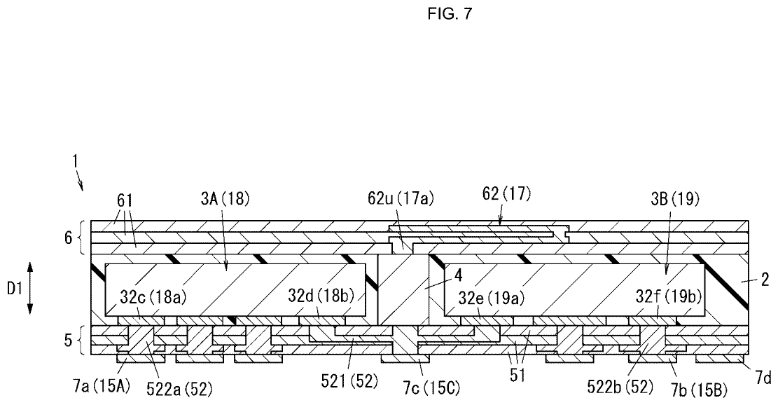

A correspondence relation between the resin-sealed component 1 according to Embodiment 3 and the circuit in FIG. 6 will be explained with reference to FIG. 7. In Embodiment 3, the chip-type electronic component 3A of the resin-sealed component 1 is the transmission filter 18. The pad electrode 32c of the chip-type electronic component 3A is the input portion 18a of the transmission filter 18. The pad electrode 32c is electrically connected to the external terminal electrode 7a being the input terminal 15A through the connection electrode layer 522a of the first thin film conductive layer 52. The pad electrode 32d of the chip-type electronic component 3A is the output portion 18b of the transmission filter 18. The pad electrode 32d is electrically connected to the pad electrode 32e of the chip-type electronic component 3B and to an external terminal electrode 7c being the input/output terminal 15C through the connection electrode layer 521 of the first thin film conductive layer 52.

The chip-type electronic component 3B of the resin-sealed component 1 is the reception filter 19. The pad electrode 32e of the chip-type electronic component 3B is the input portion 19a of the reception filter 19. The pad electrode 32e is electrically connected to the pad electrode 32d (that is to say, the output portion 18b of the transmission filter 18) of the chip-type electronic component 3A through the connection electrode layer 521 of the first thin film conductive layer 52. The pad electrode 32f of the chip-type electronic component 3B is the output portion 19b of the reception filter 19. The pad electrode 32f is electrically connected to the external terminal electrode 7b being the output terminal 15B through a connection electrode layer 522b of the first thin film conductive layer 52.

The matching circuit 17 is included in at least one of the first thin film conductive layer 52 and the second thin film conductive layer 62 (the second thin film conductive layer 62 in the example in FIG. 7). A via electrode 62u of the second thin film conductive layer 62 corresponds to one end (a first end) 17a of the matching circuit 17. The via electrode 62u is electrically connected to the external terminal electrode 7c through the connection electrode 4 as well as the connection electrode layer 521 of the first thin film conductive layer 52. A region in the second thin film conductive layer 62 corresponding to the other end (a second end) 17b of the matching circuit 17 is electrically connected to the external terminal electrode 7d being a ground terminal through a not-illustrated connection electrode in the resin layer 2 as well as a not-illustrated connection electrode of the first thin film conductive layer 52.

As described above, according to Embodiment 3, the duplexer 16 and the matching circuit 17 can be integrated into a single component (the resin-sealed component 1), and the height of the resin-sealed component 1 can be easily reduced.

Here, in Embodiment 3, the transmission filter 18 represents an example of the transmission component through which the transmission signals pass (to be more precise, the transmission component that processes the transmission signals). The reception filter 19 represents an example of the reception component through which the reception signals pass (to be more precise, the reception component that processes the reception signals). That is to say, the resin-sealed component 1 according to Embodiment 3 represents an example of the case of being provided with the multiple chip-type electronic components 3, in which the multiple chip-type electronic components 3 include the transmission component and the reception component.

### Embodiment 4

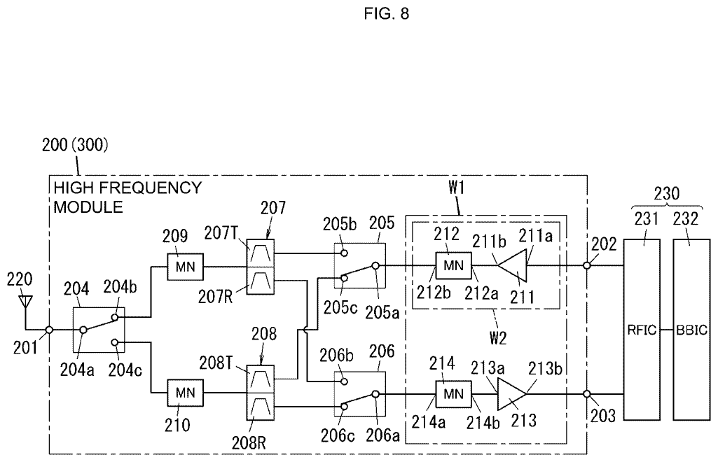

Embodiment 4 will exemplify a case where the resin-sealed component 1 includes a configuration in a range W1 of a high frequency module 200 shown in FIG. 8. Specifically, in Embodiment 4, the resin-sealed component 1 includes a power amplifier 211 (a transmission component), an output matching circuit 212 (a first circuit) connected to the power amplifier 211, a low noise amplifier 213 (a reception component), and a matching circuit 214 (a second circuit) connected to the low noise amplifier 213.

A configuration of the high frequency module 200 shown in FIG. 8 will be briefly described.

The high frequency module 200 subjects a reception signal received with an antenna 220 to signal processing (filter processing and amplification processing) and outputs the processed signal to a signal processing circuit 230. The high frequency module 200 subjects a transmission signal inputted from the signal processing circuit 230 to the signal processing (the filter processing and the amplification processing) and transmits the processed signal from the antenna 220.

The high frequency module 200 includes an antenna terminal 201, a signal input terminal 202, a signal output terminal 203, a first switch 204, a second switch 205, a third switch 206, duplexers 207 and 208, matching circuits 209 and 210, the power amplifier 211, the output matching circuit 212, the low noise amplifier 213, and the matching circuit 214.

The antenna terminal 201 is connected to the antenna 220. The signal input terminal 202 and the signal output terminal 203 are connected to a signal output portion and a signal input portion of the signal processing circuit 230, respectively.

The signal processing circuit 230 inputs the transmission signal to the signal input terminal 202 of the high frequency module 200, and subjects the reception signal outputted from the signal output terminal 203 of the high frequency module 200 to the signal processing. The signal processing circuit 230 includes an RF signal processing circuit 231 and a baseband signal processing circuit 232. The RF signal processing circuit 231 subjects the reception signal outputted from the signal output terminal 203 of the high frequency module 200 to signal processing such as down-conversion and outputs the processed signal to the baseband signal processing circuit 232. The RF signal processing circuit 231 subjects the transmission signal outputted from the baseband signal processing circuit 232 to signal processing such as up-conversion and outputs the processed signal to the signal input terminal 202 of the high frequency module 200. The baseband signal processing circuit 232 outputs the reception signal outputted from the RF signal processing circuit 231 to outside. The baseband signal processing circuit 232 generates the transmission signal from baseband signals (such as audio signals and image signals) inputted from the outside, and outputs the generated transmission signal to the RF signal processing circuit 231.

The first switch 204 includes a common terminal 204a and two selection terminals 204b and 204c. The common terminal 204a selectively establishes connection to the two selection terminals 204b and 204c. The common terminal 204a is connected to the antenna terminal 201. The selection terminal 204b is connected in common to an output portion of a transmission filter 207T to be described later and an input portion of a reception filter 207R to be described later of the duplexer 207 through the matching circuit 209. The selection terminal 204c is connected in common to an output portion of a transmission filter 208T to be described later and an input portion of a reception filter 208R to be described later of the duplexer 208 through the matching circuit 210.

The second switch 205 includes a common terminal 205a and two selection terminals 205b and 205c. The common terminal 205a selectively establishes connection to the two selection terminals 205b and 205c. The common terminal 205a is connected to the signal input terminal 202 through the output matching circuit 212 as well as the power amplifier 211. The selection terminal 205b is connected to the input portion of the transmission filter 208T to be described later of the duplexer 208. The selection terminal 205c is connected to the input portion of the transmission filter 208T to be described later of the duplexer 208.

The third switch 206 includes a common terminal 206a and two selection terminals 206b and 206c. The common terminal 206a selectively establishes connection to the two selection terminals 206b and 206c. The common terminal 206a is connected to the signal output terminal 203 through the matching circuit 214 as well as the low noise amplifier 213. The selection terminal 206b is connected to the output portion of the reception filter 207R to be described later of the duplexer 207. The selection terminal 206c is connected to the output portion of the reception filter 208R to be described later of the duplexer 208.

The duplexer 207 includes the transmission filter 207T and the reception filter 207R. The transmission filter 207T allows passage of a transmission signal in the first frequency band out of the transmission signals that are outputted from the selection terminal 205b of the second switch 205, and outputs the transmission signal allowed to pass to the selection terminal 204b of the first switch 204 through the matching circuit 209. The reception filter 207R receives reception signals outputted from the selection terminal 204b of the first switch 204 through the matching circuit 209, allows passage of a reception signal in a second frequency band out of the reception signals thus received, and outputs this reception signal to the selection terminal 206b of the third switch 206.

The duplexer 208 includes the transmission filter 208T and the reception filter 208R. The transmission filter 208T allows passage of a transmission signal in a third frequency band out of the transmission signals that are outputted from the selection terminal 205c of the second switch 205, and outputs the transmission signal allowed to pass to the selection terminal 204c of the first switch 204 through the matching circuit 210. The reception filter 208R receives reception signals outputted from the selection terminal 204c of the first switch 204 through the matching circuit 210, allows passage of a reception signal in a fourth frequency band out of the reception signals thus received, and outputs this reception signal to the selection terminal 206c of the third switch 206.

The power amplifier 211 amplifies the transmission signal from the signal input terminal 202, and outputs the amplified transmission signal to the common terminal 205a of the second switch 205 through the output matching circuit 212.

The low noise amplifier 213 receives the reception signal from the common terminal 206a of the third switch 206 through the matching circuit 214, amplifies the reception signal thus received, and outputs this signal to the signal output terminal 203.

The matching circuit 209 is connected between the first switch 204 and the duplexer 207, and carries out impedance matching between the first switch 204 and the duplexer 207. The matching circuit 210 is connected between the first switch 204 and the duplexer 208, and carries out impedance matching between the first switch 204 and the duplexer 208. The output matching circuit 212 is connected between the second switch 205 and the power amplifier 211, and carries out impedance matching between the second switch 205 and the power amplifier 211. The matching circuit 214 is connected between the third switch 206 and the low noise amplifier 213, and carries out impedance matching between the third switch 206 and the low noise amplifier 213.

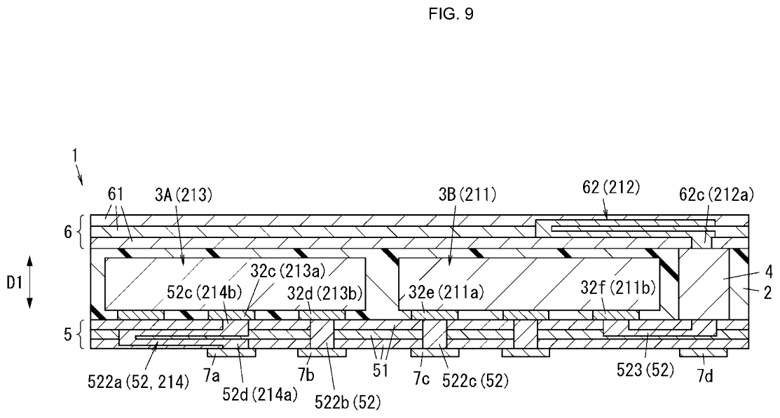

A correspondence relation between the resin-sealed component 1 according to Embodiment 4 and the configuration in the range W1 in FIG. 8 will be explained with reference to FIG. 9. In the resin-sealed component 1 according to Embodiment 4, the chip-type electronic component 3A is the low noise amplifier 213. The pad electrode 32c of the chip-type electronic component 3A is an input portion 213a of the low noise amplifier 213. The pad electrode 32d of the chip-type electronic component 3A is an output portion 213b of the low noise amplifier 213. The pad electrodes 32c and 32d are connected to the external terminal electrodes 7a and 7b, respectively, by using the connection electrode layers 522a and 522b of the first thin film conductive layer 52.

The chip-type electronic component 3B is the power amplifier 211. The pad electrode 32e of the chip-type electronic component 3B is an input portion 211a of the power amplifier 211. The pad electrode 32e is connected to the external terminal electrode 7c by using a connection electrode layer 522c of the first thin film conductive layer 52. The pad electrode 32f of the chip-type electronic component 3B is an output portion 211b of the power amplifier 211. The pad electrode 32f is connected to the second thin film conductive layer 62 through the connection electrode layer 523 of the first thin film conductive layer 52 as well as the connection electrode 4.

The matching circuit 214 is included in at least one of the first thin film conductive layer 52 and the second thin film conductive layer 62 (the first thin film conductive layer 52 in the example in FIG. 9). To be more precise, the matching circuit 214 is included in the connection electrode layer 522a of the first thin film conductive layer 52. The output matching circuit 212 is formed from the other one of the first thin film conductive layer 52 and the second thin film conductive layer 62 (the second thin film conductive layer 62 in the example in FIG. 9).

The connection electrode layer 522a (namely, the matching circuit 214) overlaps the chip-type electronic component 3A (namely, the low noise amplifier 213) in plan view in the thickness direction D1 of the resin layer 2. The via electrode 52d of the connection electrode layer 522a is an input portion 214a of the matching circuit 214, which is connected to the external terminal electrode 7a. The via electrode 52c of the connection electrode layer 522a is an output portion 214b of the matching circuit 214, which is connected to the pad electrode 32c (the input portion 213a of the low noise amplifier 213) of the chip-type electronic component 3A.

The second thin film conductive layer 62 (namely, the output matching circuit 212) overlaps the chip-type electronic component 3B (namely, the power amplifier 211) in plan view in the thickness direction D1 of the resin layer 2. A via electrode 62c of the second thin film conductive layer 62 is an input portion 212a of the output matching circuit 212. The via electrode 62c is connected to the pad electrode 32f (the output portion 211b of the power amplifier 211) through the connection electrode 4 as well as the connection electrode layer 523. A via electrode (not shown) corresponding to an output portion 212b of the output matching circuit 212 in the second thin film conductive layer 62 is connected to an external terminal electrode 7d through a not-illustrated connection electrode in the resin layer 2 as well as a not-illustrated connection electrode layer in the first thin film conductive layer 52.

In Embodiment 4, the low noise amplifier 213 represents an example of the reception component through which the reception signals pass. The matching circuit 214 represents an example of the circuit (the second circuit) connected to the reception component. The power amplifier 211 represents an example of the transmission component through which the transmission signals pass. The output matching circuit 212 represents an example of the circuit (the first circuit) connected to the transmission component. That is to say, the resin-sealed component 1 according to Embodiment 4 represents an example of the case of being provided with the multiple chip-type electronic components 3, in which the multiple chip-type electronic components 3 include the transmission component and the reception component.

According to Embodiment 4, the power amplifier 211, the low noise amplifier 213, the output matching circuit 212, and the matching circuit 214 can be integrated into a single component (the resin-sealed component 1), and the height of the resin-sealed component 1 can be easily reduced. The output matching circuit 212 (that is to say, the circuit connected to the transmission component) and the matching circuit 214 (that is to say, the circuit connected to the reception component) can separately be disposed on the front and back of the resin layer 2 of the resin-sealed component 1. As a consequence, it is possible to secure electromagnetic isolation between the output matching circuit 212 and the matching circuit 214.

### Embodiment 5

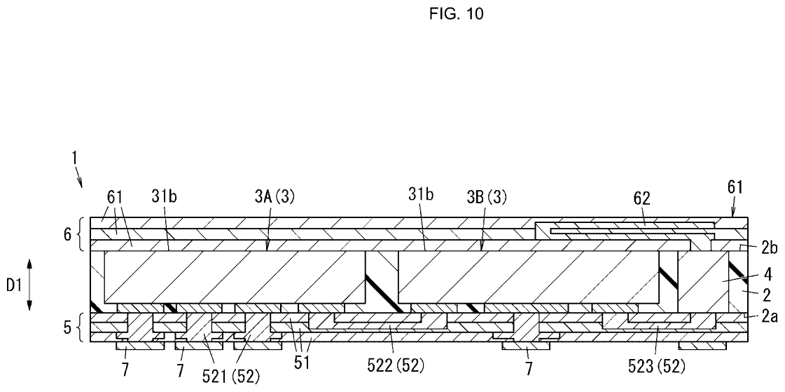

As shown in FIG. 10, the resin-sealed component 1 according to Embodiment 5 has the same configuration as that of the resin-sealed component 1 according to Embodiment 1 except that the fourth principal surfaces 31b of the two chip-type electronic components 3A and 3B are formed flush with the second principal surface 2b of the resin layer 2.

In Embodiment 5, the second wiring layer 6 is formed so as to cover the second principal surface 2b of the resin layer 2 and the fourth principal surfaces 31b of the chip-type electronic components 3. To be more precise, the second inorganic thin film insulating layer 61 is provided so as to cover the second principal surface 2b of the resin layer 2 as well as the fourth principal surfaces 31b of the two chip-type electronic components 3A and 3B. Moreover, the second inorganic thin film insulating layer 61 is provided with the second thin film conductive layer 62.

As for a method forming the fourth principal surfaces 31b of the two chip-type electronic components 3A and 3B to be flush with the second principal surface 2b of the resin layer 2, the two chip-type electronic components 3A and 3B and the connection electrode 4 are provided inside the resin layer 2 based on the manufacturing method of Embodiment 1. Then, the second principal surface 2b of the resin layer 2 is polished with a polishing apparatus until the fourth principal surfaces 31b of the two chip-type electronic components 3A and 3B are exposed.

According to Embodiment 5, the fourth principal surfaces 31b of the chip-type electronic components 3A and 3B are not covered with the resin layer 2. For this reason, the thickness in the thickness direction D1 of the resin layer 2 can be reduced in an amount equivalent to the fourth principal surfaces 31b not covered with the resin layer 2. As a consequence, the height of the resin-sealed component 1 can be even more easily reduced.

Here, Embodiment 5 exemplifies the case where all of the fourth principal surfaces 31b of the multiple chip-type electronic components 3 provided inside the resin layer 2 are formed flush with the second principal surface 2b of the resin layer 2. Nonetheless, at least one of the fourth principal surfaces 31b of the multiple chip-type electronic components 3 may be formed flush with the second principal surface 2b of the resin layer 2. For example, the fourth principal surface 31b of the chip-type electronic component 3 having the largest height from the first principal surface 2a of the resin layer 2 to the fourth principal surface 31b of the relevant chip-type electronic component 3 out of the multiple chip-type electronic components 3 may be formed flush with the second principal surface 2b of the resin layer 2.

Note that in Embodiment 5, the fourth principal surfaces 31b of the chip-type electronic components 3 (namely, the principal surfaces on the side opposite from the pad electrodes 32) are disposed on the second principal surface 2b side of the resin layer 2. Accordingly, the fourth principal surfaces 31b of the chip-type electronic components 3 are formed flush with the second principal surface 2b of the resin layer 2. Instead, the fourth principal surfaces 31b of the chip-type electronic components 3 are formed flush with the first principal surface 2a of the resin layer 2 in a configuration in which the fourth principal surfaces 31b of the chip-type electronic components 3 are disposed on the first principal surface 2a side of the resin layer 2. In other words, the fourth principal surfaces 31b of the chip-type electronic components 3 are formed flush with the first principal surface 2a or the second principal surface 2b of the resin layer 2. Note that in the configuration in which the fourth principal surfaces 31b of the chip-type electronic components 3 are disposed on the first principal surface 2a side of the resin layer 2, the external terminal electrodes 7 are provided on the outer principal surface of the second wiring layer 6 instead of being provided on the outer principal surface of the first wiring layer 5. Moreover, the connection electrode layers 521 to 523 of the first thin film conductive layer 52 are formed by using the second thin film conductive layer 62 instead of being formed by using the first thin film conductive layer 52.

### Embodiment 6

Embodiment 6 will describe an example of a high frequency module 300 that includes the resin-sealed component 1 according to Embodiment 1. Here, the high frequency module 300 may include any one of the resin-sealed components 1 according to Embodiments 2 to 5 instead of the resin-sealed component 1 according to Embodiment 1.

For example, the high frequency module 300 includes the same circuit configuration (see FIG. 8) as that of the high frequency module 200 described in Embodiment 4. In the high frequency module 300, chip-type electronic components (the power amplifier 211 and the output matching circuit 212) in a range W2 of the above-described circuit configuration (see FIG. 8) are constructed by the resin-sealed component 1, for instance.

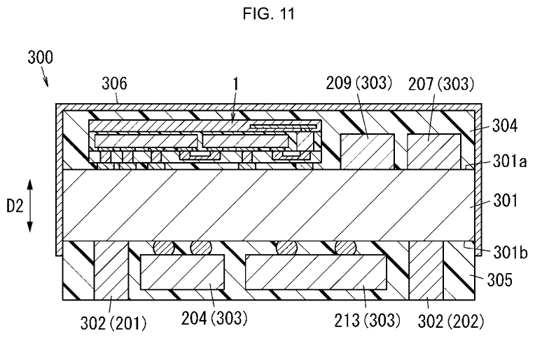

As shown in FIG. 11, the high frequency module 300 includes a mounting substrate 301, multiple external connection electrodes 302, multiple chip-type electronic components 303, the resin-sealed component 1, a first resin layer 304, a second resin layer 305, and a shield layer 306. The multiple external connection electrodes 302 include the antenna terminal 201, the signal input terminal 202, and the signal output terminal 203.

The resin-sealed component 1 includes the chip-type electronic components in the range W2 (namely, the power amplifier 211 and the output matching circuit 212), for example, out of the circuit configuration in FIG. 8. The multiple chip-type electronic components 303 are the chip-type electronic components other than the power amplifier 211 and the output matching circuit 212 out of the circuit configuration in FIG. 8.

The mounting substrate 301 is a substrate for mounting the multiple chip-type electronic components 303. The mounting substrate 301 has two principal surfaces (a fifth principal surface 301a and a sixth principal surface 301b) which are located opposite from each other in a thickness direction D2 of the mounting substrate 301.

The resin-sealed component 1, and the matching circuits 209, 210, and 214 as well as the duplexers 207 and 208 out of the multiple chip-type electronic components 303 are mounted on the fifth principal surface 301a of the mounting substrate 301, for example. Note that only the matching circuit 209 and the duplexer 207 out of the multiple chip-type electronic components 303 to be mounted on the fifth principal surface 301a of the mounting substrate 301 (namely, the matching circuits 209, 210, and 214, and the duplexers 207 and 208) are illustrated in FIG. 11.

The multiple external connection electrodes 302 as well as the low noise amplifier 213, the first switch 204, the second switch 205, and the third switch 206 out of the multiple chip-type electronic components 303 are mounted on the sixth principal surface 301b of the mounting substrate 301. Note that only the low noise amplifier 213 and the first switch 204 out of the multiple chip-type electronic components 303 to be mounted on the sixth principal surface 301b of the mounting substrate 301 (namely, the low noise amplifier 213, the first switch 204, the second switch 205, and the third switch 206) are illustrated in FIG. 11. Only the antenna terminal 201 and the signal input terminal 202 out of the multiple external connection electrodes 302 are illustrated therein.

The first resin layer 304 is provided on the fifth principal surface 301a of the mounting substrate 301. The first resin layer 304 covers the resin-sealed component 1 and the multiple chip-type electronic components 303 which are mounted on the fifth principal surface 301a of the mounting substrate 301.

The second resin layer 305 is provided on the sixth principal surface 301b of the mounting substrate 301. The second resin layer 305 covers the multiple external connection electrodes 302 and the multiple chip-type electronic components 303 which are mounted on the sixth principal surface 301b of the mounting substrate 301. To be more precise, regarding the chip-type electronic components 303, the second resin layer 305 covers the entire outer surfaces thereof. Regarding the external connection electrodes 302, the second resin layer 305 exposes tip end surfaces thereof and covers portions (outer peripheral surfaces) other than the tip end surfaces.

The shield layer 306 is made of a metal, for example. The shield layer 306 is provided on outer surfaces (outer peripheral surfaces and an outer principal surface) of the first resin layer 304, outer peripheral surfaces of the second resin layer 305, and outer peripheral surfaces of the mounting substrate 301. To be more precise, the shield layer 306 convers the entire outer surfaces of the first resin layer 304, the entire outer peripheral surfaces of the mounting substrate 301, and part of the outer peripheral surfaces of the second resin layer 305.

According to Embodiment 6, it is possible to provide the high frequency module 300 that has the advantages of the resin-sealed component 1.

### Aspects

The embodiments and the modification described above disclose the following aspects.

A resin-sealed component (1) according to a first aspect includes a resin layer (2), at least one chip-type electronic component (3A, 3B), a first inorganic thin film insulating layer (51), and a first thin film conductive layer (52). The resin layer (2) includes a first principal surface (2a) and a second principal surface (2b) located opposite from each other. The at least one chip-type electronic component (3A, 3B) is provided inside the resin layer (2). The first inorganic thin film insulating layer (51) is provided on or to the first principal surface (2a) of the resin layer (2). The first thin film conductive layer (52) is provided in the first inorganic thin film insulating layer (51).

According to this configuration, the first inorganic thin film insulating layer (51) is formed from an inorganic material. For this reason, it is possible to make the first inorganic thin film insulating layer (51) thinner as compared to a configuration in which a resin or a ceramic is provided on the first principal surface (2a) of the resin layer (2). As a consequence, it is easier to reduce the height of the resin-sealed component (1).

A second aspect provides the resin-sealed component (1) according to the first aspect, which further includes a second inorganic thin film insulating layer (61) and a second thin film conductive layer (62). The second inorganic thin film insulating layer (61) is provided on or to the second principal surface (2b) of the resin layer (2). The second thin film conductive layer (62) is provided in the second inorganic thin film insulating layer (61).

According to this configuration, the second inorganic thin film insulating layer (61) is formed from an inorganic material. For this reason, it is possible to make the second inorganic thin film insulating layer (61) thinner as compared to a configuration in which a resin or a ceramic is provided on the second principal surface (2b) of the resin layer (2). As a consequence, it is even easier to reduce the height of the resin-sealed component (1) in the configuration in which the inorganic thin film insulating layers (the first inorganic thin film insulating layer (51) and the second inorganic thin film insulating layer (61)) and the thin film conductive layers (the first thin film conductive layer (52) and the second thin film conductive layer (62)) are provided on the respective principal surfaces (the first principal surface (2a) and the second principal surface (2b)) of the resin layer (2).

A third aspect provides the resin-sealed component (1) according to the second aspect, in which at least one of the first inorganic thin film insulating layer (51) and the second inorganic thin film insulating layer (61) is any of an oxide film, a nitride film, and an oxynitride film.

According to this configuration, at least one of the first inorganic thin film insulating layer (51) and the second inorganic thin film insulating layer (61) can be formed easily into a thin film form.

A fourth aspect provides the resin-sealed component (1) according to the second or third aspect, which includes a plurality of multiple chip-type electronic components (3). The multiple chip-type electronic components (3A, 3B) include a first IC chip (14A; 14C) and a second IC chip (14B). The first IC chip (14A; 14C) includes a first amplifier (121b) being an amplifier on a signal input side out of multiple amplifiers constituting a power amplifier (12). The second IC chip (14B) includes a second amplifier (123a, 123b) being an amplifier on a signal output side out of the multiple amplifiers constituting the power amplifier (12).

According to this configuration, the first amplifier (121b) and the second amplifier (123a, 123b) constituting the power amplifier (12) can be constructed by a single component (the resin-sealed component (1)), and the height of the resin-sealed component (1) can be easily reduced.

A fifth aspect provides the resin-sealed component (1) according to the fourth aspect, in which at least one of the first thin film conductive layer (52) and the second thin film conductive layer (62) includes an output matching circuit (13) connected to an output portion of the second amplifier (123a, 123b). The output matching circuit (13) overlaps the second IC chip (14B) in plan view in a thickness direction (D1) of the resin layer (2).

According to this configuration, the output matching circuit (13) is included in at least one of the first thin film conductive layer (52) and the second thin film conductive layer (62). Therefore, the height of the resin-sealed component (1) can be easily reduced in the configuration in which the resin-sealed component (1) includes the output matching circuit (13). Since the output matching circuit (13) overlaps the second IC chip (14B), it is possible to secure electromagnetic isolation between the output matching circuit (13) and other components in the resin-sealed component (1).

A sixth aspect provides the resin-sealed component (1) according to the fourth or fifth aspect, in which the first IC chip (14A) includes a matching circuit (122) connected to an output portion of the first amplifier (121b).

According to this configuration, the matching circuit (122) and the first amplifier (121b) are included in the same first IC chip (14A). It is therefore easy to adjust impedance matching between the matching circuit (122) and the first amplifier (121b).

A seventh aspect provides the resin-sealed component (1) according to the fourth or fifth aspect, in which at least one of the first thin film conductive layer (52) and the second thin film conductive layer (62) includes a matching circuit (122) connected to an output portion of the first amplifier (121b).

According to this configuration, the matching circuit (122) is included in at least one of the first thin film conductive layer (52) and the second thin film conductive layer (62), and the first IC chip (14C) therefore does not include the matching circuit (122). As a consequence, it is possible to downsize the first IC chip (14C).

An eighth aspect provides the resin-sealed component (1) according to the second or third aspect, which includes multiple chip-type electronic components (3). The multiple chip-type electronic components (3A, 3B) include a transmission component (18; 211) through which a transmission signal passes, and a reception component (19; 213) through which a reception signal passes.

According to this configuration, the transmission component (18; 211) and the reception component (19; 213) can be integrated into a single component (the resin-sealed component (1)), and the height of the resin-sealed component (1) can be easily reduced.

A ninth aspect provides the resin-sealed component (1) according to the eighth aspect, in which one of the first thin film conductive layer (52) and the second thin film conductive layer (62) includes a first circuit (212) connected to the transmission component (211). Another one of the first thin film conductive layer (52) and the second thin film conductive layer (62) includes a second circuit (214) connected to the reception component (213).

According to this configuration, the transmission component (211), the reception component (213), the first circuit (212), and the second circuit (214) can be integrated into a single component (the resin-sealed component (1)), and the height of the resin-sealed component (1) can be easily reduced. The first circuit (212) and the second circuit (214) can separately be disposed on the front and back of the resin layer (2) of the resin-sealed component (1). As a consequence, it is possible to secure electromagnetic isolation between the first circuit (212) and the second circuit (214).

A tenth aspect provides the resin-sealed component (1) according to the eighth aspect, in which the transmission component (18) is a transmission filter (18). The reception component (19) is a reception filter (19). At least one of the first thin film conductive layer (52) and the second thin film conductive layer (62) includes a matching circuit (17) connected to both of an output portion of the transmission filter (18) and an input portion of the reception filter (19).

According to this configuration, a duplexer (16) which includes the transmission filter (18) and the reception filter (19), and the matching circuit (17) connected to the duplexer (16) can be integrated into a single component (the resin-sealed component (1)), and the height of the resin-sealed component (1) can be easily reduced.

An eleventh aspect provides the resin-sealed component (1) according to any one of the first to tenth aspects, in which the at least one chip-type electronic component (3A, 3B) includes a component body (31) and a pad electrode (32). The component body (31) includes a third principal surface (31a) and a fourth principal surface (31b) located opposite from each other. The pad electrode (32) is provided on the third principal surface (31a). The fourth principal surface (31b) of the component body (31) is flush with one of the first principal surface (2a) and the second principal surface (2b) of the resin layer (2).

According to this configuration, the fourth principal surface (31b) of the chip-type electronic component (3A, 3B) is flush with the first principal surface (2a) or the second principal surface (2b) of the resin layer (2). For this reason, the thickness (D1) of the resin layer (2) can be reduced in an amount equivalent to the fourth principal surface (31b) of the chip-type electronic component (3A, 3B) not covered with the resin layer (2). As a consequence, the height of the resin-sealed component (1) can be even more easily reduced.

A high frequency module (300) according to a twelfth aspect includes the resin-sealed component (1) according to any one of the first to eleventh aspects, and a mounting substrate (301) on which the resin-sealed component (1) is disposed.

According to this configuration it is possible to provide the high frequency module (300) that has the advantages of the resin-sealed component (1).
1 resin-sealed component
2 resin layer
2a first principal surface
2b second principal surface
3, 3A, 3B chip-type electronic component
4 connection electrode
5 first wiring layer
5a outer principal surface
6 second wiring layer
7, 7a to 7d external terminal electrode
10 input terminal
11 output terminal
12 power amplifier
13 output matching circuit
13p input portion
13q output portion
14A, 14C first IC chip
14B second IC chip
15A input terminal
15B output terminal
15C input/output terminal
16 duplexer
17 matching circuit
17a one end
   17b one end
18 transmission filter (transmission component)
18a input portion
18b output portion
19 reception filter (reception component)
19a input portion
19b output portion
21 RF signal processing circuit
22 baseband signal processing circuit
31 component body
31a third principal surface
31b fourth principal surface
31c outer peripheral surface
32, 32a to 32f pad electrode
32s contact surface
51 first inorganic thin film insulating layer
52 first thin film conductive layer
52a conductive layer
52b, 52c, 52d via electrode
61 second inorganic thin film insulating layer
62 second thin film conductive layer
62a conductive layer
62b, 62c, 62u via electrode
121 driver stage
121a matching circuit
121b first amplifier
121p input portion
121q output portion
122 interstage matching circuit (matching circuit)
122p input portion
122q output portion
123 final stage
123a second amplifier
123b second amplifier
123p input portion
123q output portion
200 high frequency module
201 antenna terminal
202 signal input terminal
203 signal output terminal
204 first switch
204a common terminal
204b selection terminal
204c selection terminal
205 second switch
205a common terminal
205b selection terminal
205c selection terminal
206 third switch
206a common terminal
206b selection terminal
206c selection terminal
207, 208 duplexer
207R, 208R reception filter
207T, 208T transmission filter
209, 210 matching circuit
211 power amplifier (transmission component)
211a input portion
211b output portion
212 output matching circuit (first circuit)
212a input portion
212b output portion
213 low noise amplifier (reception component)
213a input portion
213b output portion
214 matching circuit (second circuit)
214a input portion
220 antenna
230 signal processing circuit
231 RF signal processing circuit
232 baseband signal processing circuit
300 high frequency module
301 mounting substrate
301a fifth principal surface
301b sixth principal surface
302 external connection electrode
303 chip-type electronic component
304 first resin layer
305 second resin layer
305a fifth principal surface
306 shield layer
521, 522, 522a to 522c, 523 connection electrode layer
C1 to C4 capacitor
D1, D2 thickness direction
L1, L3 primary coil
L2, L4 secondary coil
N1, N2 node
T1, T2 transformer
W1, W2 range

1. A resin-sealed component comprising:
a resin layer including a first principal surface and a second principal surface located opposite from each other;
at least one chip-type electronic component provided inside the resin layer;
a first inorganic thin film insulating layer provided on or to the first principal surface of the resin layer; and
a first thin film conductive layer provided in the first inorganic thin film insulating layer.

2. The resin-sealed component according to claim 1, further comprising:
a second inorganic thin film insulating layer provided on or to the second principal surface of the resin layer; and
a second thin film conductive layer provided in the second inorganic thin film insulating layer.

3. The resin-sealed component according to claim 2, wherein at least one of the first inorganic thin film insulating layer and the second inorganic thin film insulating layer is any of an oxide film, a nitride film, and an oxynitride film.

4. The resin-sealed component according to claim 2, wherein
the at least one chip-type electronic component includes a plurality of chip-type electronic components, and
the plurality of chip-type electronic components includes
a first IC chip including a first amplifier being an amplifier on a signal input side out of a plurality of amplifiers constituting a power amplifier, and
a second IC chip including a second amplifier being an amplifier on a signal output side out of the plurality of amplifiers constituting the power amplifier.

5. The resin-sealed component according to claim 4, wherein
at least one of the first thin film conductive layer and the second thin film conductive layer includes an output matching circuit connected to an output portion of the second amplifier, and
the output matching circuit overlaps the second IC chip in plan view in a thickness direction of the resin layer.

6. The resin-sealed component according to claim 4, wherein the first IC chip includes a matching circuit connected to an output portion of the first amplifier.

7. The resin-sealed component according to claim 4, wherein at least one of the first thin film conductive layer and the second thin film conductive layer includes a matching circuit connected to an output portion of the first amplifier.

8. The resin-sealed component according to claim 2, wherein
the at least one chip-type electronic component includes a plurality of chip-type electronic components, and
the plurality of chip-type electronic components includes
a transmission component through which a transmission signal passes, and
a reception component through which a reception signal passes.

9. The resin-sealed component according to claim 8, wherein
one of the first thin film conductive layer and the second thin film conductive layer includes a first circuit connected to the transmission component, and
another one of the first thin film conductive layer and the second thin film conductive layer includes a second circuit connected to the reception component.

10. The resin-sealed component according to claim 8, wherein
the transmission component is a transmission filter,
the reception component is a reception filter, and
at least one of the first thin film conductive layer and the second thin film conductive layer includes a matching circuit connected to both of an output portion of the transmission filter and an input portion of the reception filter.

11. The resin-sealed component according to claim 1, wherein
the at least one chip-type electronic component includes
a component body including a third principal surface and a fourth principal surface located opposite from each other, and
a pad electrode provided on the third principal surface, and
the fourth principal surface of the component body is flush with one of the first principal surface and the second principal surface of the resin layer.

12. A high frequency module comprising:
the resin-sealed component according to claim 1; and
a mounting substrate on which the resin-sealed component is disposed.

13. The resin-sealed component according to claim 3, wherein
the at least one chip-type electronic component includes a plurality of chip-type electronic components, and
the plurality of chip-type electronic components includes
a first IC chip including a first amplifier being an amplifier on a signal input side out of a plurality of amplifiers constituting a power amplifier, and
a second IC chip including a second amplifier being an amplifier on a signal output side out of the plurality of amplifiers constituting the power amplifier.

14. The resin-sealed component according to claim 5, wherein the first IC chip includes a matching circuit connected to an output portion of the first amplifier.

15. The resin-sealed component according to claim 5, wherein at least one of the first thin film conductive layer and the second thin film conductive layer includes a matching circuit connected to an output portion of the first amplifier.

16. The resin-sealed component according to claim 3, wherein
the at least one chip-type electronic component includes a plurality of chip-type electronic components, and
the plurality of chip-type electronic components includes
a transmission component through which a transmission signal passes, and
a reception component through which a reception signal passes.

17. The resin-sealed component according to claim 2, wherein
the at least one chip-type electronic component includes
a component body including a third principal surface and a fourth principal surface located opposite from each other, and
a pad electrode provided on the third principal surface, and
the fourth principal surface of the component body is flush with one of the first principal surface and the second principal surface of the resin layer.

18. The resin-sealed component according to claim 3, wherein
the at least one chip-type electronic component includes
a component body including a third principal surface and a fourth principal surface located opposite from each other, and
a pad electrode provided on the third principal surface, and
the fourth principal surface of the component body is flush with one of the first principal surface and the second principal surface of the resin layer.

19. The resin-sealed component according to claim 4, wherein
the at least one chip-type electronic component includes
a component body including a third principal surface and a fourth principal surface located opposite from each other, and
a pad electrode provided on the third principal surface, and
the fourth principal surface of the component body is flush with one of the first principal surface and the second principal surface of the resin layer.

20. The resin-sealed component according to claim 5, wherein
the at least one chip-type electronic component includes
a component body including a third principal surface and a fourth principal surface located opposite from each other, and
a pad electrode provided on the third principal surface, and
the fourth principal surface of the component body is flush with one of the first principal surface and the second principal surface of the resin layer.
